(19) United States
(12) Patent Application Publication
(10) Pub. No.: US 2024/0421123 A1
(43) Pub. Date: Dec. 19, 2024

(54) SEMICONDUCTOR PACKAGE AND MANUFACTURING METHOD THEREOF

(71) Applicant: Samsung Electronics Co., Ltd., Suwon-si (KR)

(72) Inventors: Chengtar Wu, Suwon-si (KR); CHOONGBIN YIM, Suwon-si (KR)

(21) Appl. No.: 18/406,800

(22) Filed: Jan. 8, 2024

(30) Foreign Application Priority Data
Jun. 15, 2023 (KR) 10-2023-0076852

(51) Int. Cl. H01L 25/065; H01L 23/00; H01L 23/31; H01L 23/48; H01L 23/538

(52) U.S. Cl. CPC H01L 25/0655; H01L 23/3121; H01L 23/481; H01L 23/5383; H01L 24/16; H01L 24/32; H01L 24/45; H01L 24/48; H01L 24/73; H01L 2224/16227; H01L 2224/32225; H01L 2224/45139; H01L 2224/45144; H01L 2224/45147; H01L 2224/48137; H01L 2224/73204

(57) ABSTRACT

A semiconductor package includes: a substrate; a first semiconductor structure on the substrate, wherein the first semiconductor structure includes a first redistribution layer structure and a first semiconductor die that is disposed on the first redistribution layer structure and includes a plurality of first through-semiconductor vias; a second semiconductor structure disposed side by side with the first semiconductor structure on the substrate, wherein the second semiconductor structure includes a second redistribution layer structure and a second semiconductor die that is disposed on the second redistribution layer structure and includes a plurality of second through-semiconductor vias; a plurality of bonding wires electrically connecting the first semiconductor die and the second semiconductor die on the first semiconductor die and the second semiconductor die; and a molding material surrounding the plurality of bonding wires and through which the plurality of bonding wires pass.

### CROSS-REFERENCE TO RELATED APPLICATION

This application claims priority to and the benefit of Korean Patent Application No. 10-2023-0076852 filed in the Korean Intellectual Property Office on Jun. 15, 2023, the entire contents of which are incorporated herein by reference.

### BACKGROUND OF THE INVENTION

### (a) Field of the Invention

The present invention relates to a semiconductor package and a manufacturing method thereof.

### (b) Description of the Related Art

A semiconductor chip manufactured by applying a fine process is typically electrically coupled to a semiconductor substrate in order to transmit and receive signals with other semiconductor chips. However, since the semiconductor substrate has a relatively large circuit line width compared to the semiconductor chip to which the fine process is applied, in order to connect the semiconductor chip to which the fine process is applied and the semiconductor substrate, an intermediate medium that may decrease the difference in line width between the semiconductor chip to which the fine process is applied and the semiconductor substrate is used.

As the intermediate medium, a silicon bridge applied with a fine process is well known. The silicon bridge is embedded in a semiconductor substrate, and a semiconductor package using the silicon bridge has a structure in which semiconductor chips are mounted on a semiconductor substrate in which the silicon bridge is embedded and the silicon bridge and the semiconductor chips are connected.

The silicon bridge is attached within the semiconductor substrate by using a die attached film (DAF) or adhesive, and the DAF or adhesive may have fluidity in a subsequent heat treatment process. Accordingly, the silicon bridge may be moved due to the fluidity of the DAF or adhesive. In addition, in the process of embedding the silicon bridge in the semiconductor substrate, the silicon bridge may be incorrectly attached to the semiconductor substrate. Likewise, if the silicon bridge moves during the manufacturing process or is attached incorrectly, the yield of the semiconductor package will decrease.

Furthermore, as the integration density of passive or active devices within a given area of a semiconductor package increases, more silicon bridges are required. In this case, the structure of the semiconductor package is inevitably more complicated to correct an overlay error between the silicon bridges caused by the movement of the silicon bridges or the incorrect attachment of the silicon bridges during the manufacturing process.

In addition, the silicon bridge is embedded in the semiconductor substrate. The main material of the silicon bridge is silicon, and the main material of the semiconductor substrate is an organic material having a higher coefficient of thermal expansion (CTE) than silicon. Accordingly, a warpage may occur in the semiconductor package due to a difference in the CTE between the silicon bridge and the semiconductor substrate.

Therefore, it would be useful to develop a new semiconductor package technology that may address these issues.

### SUMMARY OF THE INVENTION

In order to improve the issues during the manufacturing process, such as the silicon bridge moving and the silicon bridge being incorrectly attached, and the warpage problem of the semiconductor package due to the silicon bridge, a first semiconductor die and a second semiconductor die disposed side by side on a substrate may be electrically connected with a plurality of bonding wires without using a silicon bridge. For example, a semiconductor package in which signals between high performance circuits in the first semiconductor die and the second semiconductor die are exchanged through the plurality of bonding wires, and signals between low performance circuits in the first semiconductor die and the second semiconductor die are exchanged through the substrate, may be provided.

An embodiment provides a semiconductor package including: a substrate; a first semiconductor structure on the substrate, wherein the first semiconductor structure includes a first redistribution layer structure and a first semiconductor die that is disposed on the first redistribution layer structure and includes a plurality of first through-semiconductor vias; a second semiconductor structure disposed side by side with the first semiconductor structure on the substrate, wherein the second semiconductor structure includes a second redistribution layer structure and a second semiconductor die that is disposed on the second redistribution layer structure and includes a plurality of second through-semiconductor vias; a plurality of bonding wires electrically connecting the first semiconductor die and the second semiconductor die on the first semiconductor die and the second semiconductor die.

Another embodiment provides a semiconductor package including: a substrate; a first semiconductor structure on the substrate, wherein the first semiconductor structure includes a first redistribution layer structure, a plurality of first connection terminals electrically connecting the first redistribution layer structure to the substrate, a first insulating member surrounding the plurality of first connection terminals between the substrate and the first redistribution layer structure, and a first semiconductor die that is disposed on the first redistribution layer structure and includes a plurality of first through-semiconductor vias; a second semiconductor structure disposed side by side with the first semiconductor structure on the substrate, wherein the second semiconductor structure includes a second redistribution layer structure, a plurality of second connection terminals electrically connecting the second redistribution layer structure to the substrate, a second insulating member surrounding the plurality of second connection terminals between the substrate and the second redistribution layer structure, and a second semiconductor die that is disposed on the second redistribution layer structure and includes a plurality of second through-semiconductor vias; and a plurality of bonding wires electrically connecting the first semiconductor die and the second semiconductor die on the first semiconductor die and the second semiconductor die.

By electrically connecting a first semiconductor die and a second semiconductor die disposed side by side on a substrate with a plurality of bonding wires, it is possible to provide a semiconductor package in which signals between high-performance circuits in the first semiconductor die and the second semiconductor die are exchanged through the plurality of bonding wires, signals between low-performance circuits in the first semiconductor die and the second semiconductor die are exchanged through the substrate, and a silicon bridge is not used.

Accordingly, since the silicon bridge is not used, the problem in which the silicon bridge moves or the silicon bridge is incorrectly attached during the manufacturing process, and the warpage problem of the semiconductor package due to the silicon bridge are avoided, thereby improving the yield of the semiconductor package.

In addition, when a silicon bridge is used, the manufacturing process is more complicated because the silicon bridge is embedded in the substrate, while by not using the silicon bridge, the manufacturing process of the semiconductor package may be simplified.

### BRIEF DESCRIPTION OF THE DRAWINGS

FIG. 1 illustrates a cross-sectional view of a semiconductor structure included in a semiconductor package of an embodiment.

FIG. 2 to FIG. 8 illustrate cross-sectional views of a method of manufacturing a semiconductor structure of an embodiment.

FIG. 9 illustrates a cross-sectional view of a semiconductor package according to an embodiment.

FIG. 10 illustrates a top plan view of an upper surface of a semiconductor package according to an embodiment.

FIG. 11 to FIG. 16 illustrate cross-sectional views of a method of manufacturing a semiconductor package of an embodiment.

### DETAILED DESCRIPTION OF THE EMBODIMENTS

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

The drawings and description are to be regarded as illustrative in nature and not restrictive. Like reference numerals designate like elements throughout the specification.

Further, in the drawings, the size and thickness of each element are arbitrarily illustrated for ease of description, and the present disclosure is not necessarily limited to those illustrated in the drawings.

Throughout this specification and the claims that follow, when it is described that an element is “coupled or connected” to another element, the element may be “directly coupled or connected” to the other element or “indirectly coupled or connected” to the other element through a third element. The term “contact,” “contacting,” “contacts,” or “in contact with,” as used herein, refers to a direct connection (i.e., touching) unless the context clearly indicates otherwise. In addition, unless explicitly described to the contrary, the word “comprise” and variations such as “comprises” or “comprising” will be understood to imply the inclusion of stated elements but not the exclusion of any other elements.

It will be understood that when an element such as a layer, film, region, area, or substrate is referred to as being “on” or “above” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

Items described in the singular herein may be provided in plural, as can be seen, for example, in the drawings. Thus, the description of a single item that is provided in plural should be understood to be applicable to the remaining plurality of items unless context indicates otherwise.

Hereinafter, a semiconductor package 200 and a manufacturing method of the semiconductor package 200 according to an embodiment will be described with reference to the accompanying drawings.

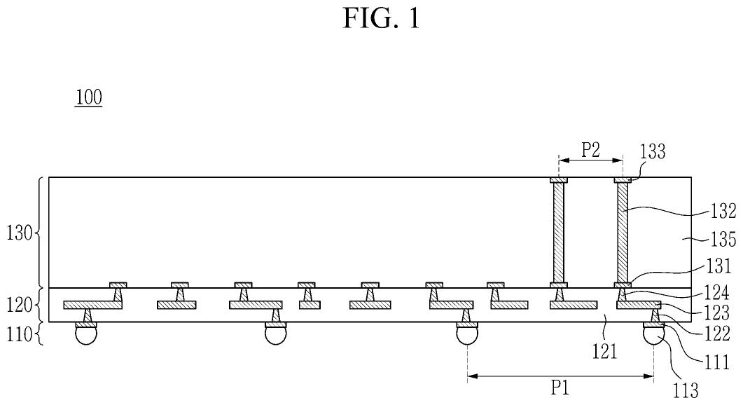

FIG. 1 illustrates a cross-sectional view of a semiconductor structure 100 included in the semiconductor package 200 of an embodiment.

Referring to FIG. 1, the semiconductor structure 100 may include a redistribution layer (RDL) structure 120 and a semiconductor die (first semiconductor die) 130. The semiconductor structure 100 may also be described as a semiconductor die structure, or semiconductor chip structure. In this embodiment, the redistribution layer structure 120 may be a redistribution layer interposer, and may also be referred to as a redistribution layer. The semiconductor die 130 may include a high performance semiconductor, which uses a high routing density and is implemented with a fine line width. Due to a pitch difference between a fine pitch I/O of the high performance semiconductor and a normal pitch I/O of the conventional substrate, it is generally not possible to electrically connect the normal pitch I/O of the conventional substrate to the fine pitch I/O of the high performance semiconductor. Accordingly, when a redistribution layer structure is disposed under the semiconductor die 130, the semiconductor die 130 and the substrate may be electrically connected by the redistribution layer structure.

The redistribution layer structure 120 may include a dielectric layer 121, and first redistribution vias 122, first redistribution lines 123, and second redistribution vias 124 within the dielectric layer 121. In another embodiment, a redistribution layer structure that include fewer or greater numbers of redistribution lines and redistribution vias is within the scope of the present disclosure.

The dielectric layer 121 protects and insulates the first redistribution vias 122, the first redistribution lines 123, and the second redistribution vias 124. The first semiconductor die 130 may be disposed on an upper surface of the dielectric layer 121, and an interconnection structure 110 may be disposed on a lower surface of the dielectric layer 121. The interconnection structure 110 may include interconnection terminals for connecting the semiconductor structure 100 to a substrate or other device outside the semiconductor structure 100.

The first redistribution via 122 may be disposed between the first redistribution line 123 and a conductive pad 111 of the interconnection structure 110. The first redistribution via 122 may electrically connect the first redistribution line 123 to the conductive pad 111 in a vertical direction. The first redistribution line 123 may be disposed between the first redistribution via 122 and the second redistribution via 124. The first redistribution line 123 may electrically connect the first redistribution via 122 and the second redistribution via 124 in a horizontal direction. The second redistribution via 124 may be disposed between the first redistribution line 123 and a lower connection pad 131 of the first semiconductor die 130. The second redistribution via 124 may electrically connect the lower connection pad 131 of the first semiconductor die 130 to the first redistribution line 123 in the vertical direction. The second redistribution via 124 may be directly connected to the lower connection pad 131 of the semiconductor die 130 with no connection member therebetween. In one embodiment, a width of an uppermost portion of each of the first redistribution via 122 and the second redistribution via 124 may be smaller than that of a lowermost portion thereof. In this embodiment, a pitch in the horizontal direction between the first redistribution vias 122 of the redistribution layer structure 120 may be greater than a pitch between the second redistribution vias 124 of the redistribution layer structure 120.

The semiconductor die 130 may include through-substrate vias such as through-silicon vias (TSV) 132 (also generally referred to as through-semiconductor vias), lower connection pads 131, upper connection pads 133, and a semiconductor chip (semiconductor integrated circuits). The various pads of a device described herein may be conductive terminals connected to internal wiring of the device, and may transmit signals and/or supply voltages between an internal wiring and/or internal circuit of the device and an external source. For example, chip pads of a semiconductor chip may electrically connect to and transmit supply voltages and/or signals between an integrated circuit of the semiconductor chip and a device to which the semiconductor chip is connected. The various pads may be provided on or near an external surface of the device and may generally have a planar surface area (often larger than a corresponding surface area of the internal wiring to which they are connected).

In some embodiments, the semiconductor chip (semiconductor integrated circuits) may include or be a high performance circuit. In some embodiments, the semiconductor die 130 may include or be a system on chip (SOC). In some embodiments, the semiconductor die 130 may include or be a memory structure, a DRAM, or high bandwidth memory (HBM). In some embodiments, the semiconductor chip may include or be at least one of a central processing unit (CPU), a graphics processing unit (GPU), a memory, a controller, a codec, a sensor, and a communication unit. In some embodiments, each of the semiconductor structure 100 and the semiconductor structure 100A may include a plurality of separate semiconductor dies, some including high performance terminals connected to respective bonding wires 160, or may include a single semiconductor die that includes some high performance terminals.

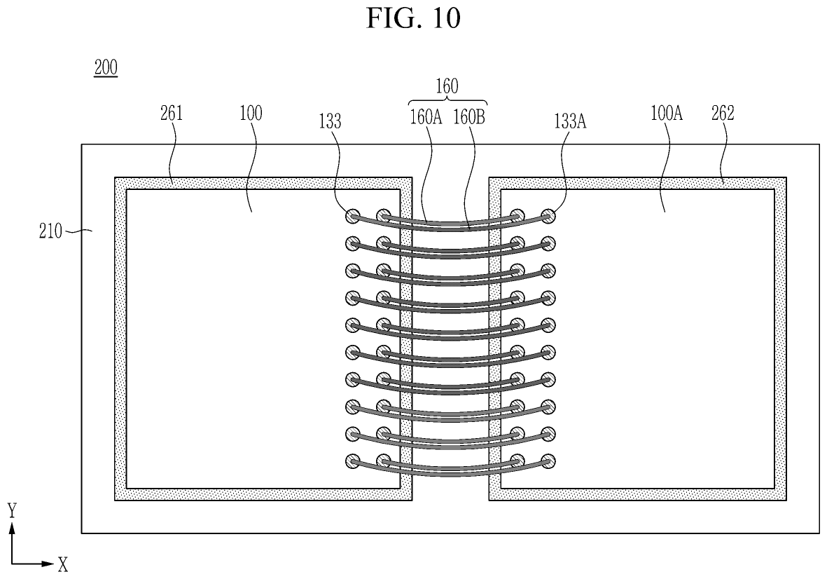

The TSV 132 may be disposed between the lower connection pad 131 and the upper connection pad 133. The TSV 132 may electrically connect the lower connection pad 131 and the upper connection pad 133. In the semiconductor package 200 (see FIG. 10) in which the semiconductor dies 130 are disposed side by side, electrical signals may be transmitted and received between the semiconductor dies 130 using a plurality of bonding wires 160 without a silicon bridge. In this case, by disposing the through-silicon vias (TSV) 132 within the semiconductor dies 130, a speed of receiving and responding to signals and power between the semiconductor dies 130 may be increased.

The lower connection pad 131 may be disposed between the through-silicon via (TSV) 132 and the second redistribution via 124. The lower connection pad 131 may electrically connect the through-silicon via (TSV) 132 to the second redistribution via 124. The upper connection pad 133 may be disposed between the through-silicon via (TSV) 132 and a bonding wire 160 (see FIG. 10). The upper connection pad 133 may electrically connect the bonding wire 160 to the through-silicon via (TSV) 132. An upper surface of the upper connection pad 133 may be exposed from an upper surface of the semiconductor die 130.

The interconnection structure 110 may be disposed on a lower surface of the redistribution layer structure 120. The interconnection structure 110 may include the conductive pads 111 and connection members 113. The conductive pad 111 may electrically connect the first redistribution via 122 of the redistribution layer structure 120 to the connection member 113. The connection member 113 may electrically connect the semiconductor structure 100 to a substrate 210 (see FIG. 10). In some embodiments, a pitch P1 between the connection members 113 is greater than a pitch P2 between the through-silicon vias 132. As described above, by disposing the redistribution layer structure 120 between the semiconductor die 130 and the substrate 210, the semiconductor die 130 including the fine pitch I/O may be electrically connected to the substrate including the normal pitch I/O. In some embodiments, the connection member 113 may be a solder ball or conductive bump.

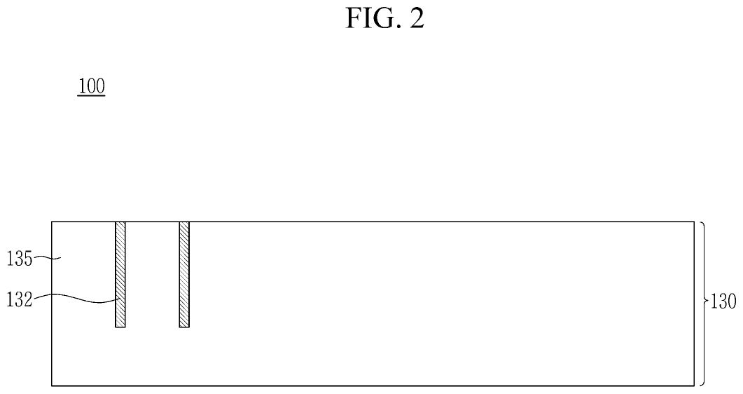

FIG. 2 to FIG. 8 illustrate cross-sectional views of a method of manufacturing the semiconductor structure 100 according to one embodiment.

FIG. 2 illustrates a cross-sectional view of a step of providing the first semiconductor die 130 having the through-silicon vias (TSV) 132 formed in a die base 135, in the manufacturing method of the semiconductor structure 100. FIG. 2 to FIG. 8 illustrate cross-sectional views of the steps of the manufacturing method of the semiconductor structure 100 of FIG. 1.

Referring to FIG. 2, the semiconductor die 130 having the through-silicon vias (TSV) 132 formed in the die base 135 is provided. The die base 135 may be formed of a semiconductor material such as silicon. The through-silicon vias (TSV) 132 are formed by forming holes penetrating a material from the die base 135 and filling the holes with a conductive material. In the embodiment, the hole of the through-silicon via (TSV) 132 may be formed by deep etching. In another embodiment, the hole of the through-silicon via (TSV) 132 may be formed by a laser. In one embodiment, the hole of the through-silicon vias (TSV) 132 may be filled with a conductive material by electrolytic plating. In one embodiment, the through-silicon vias (TSV) 132 may include or be formed of at least one of tungsten, aluminum, copper, and an alloy thereof.

A barrier layer (not shown) may be formed between the through-silicon via (TSV) 132 and the material of the die base 135. In one embodiment, the barrier layer (not shown) may include or be formed of at least one of titanium, tantalum, a titanium nitride, a tantalum nitride, and an alloy thereof.

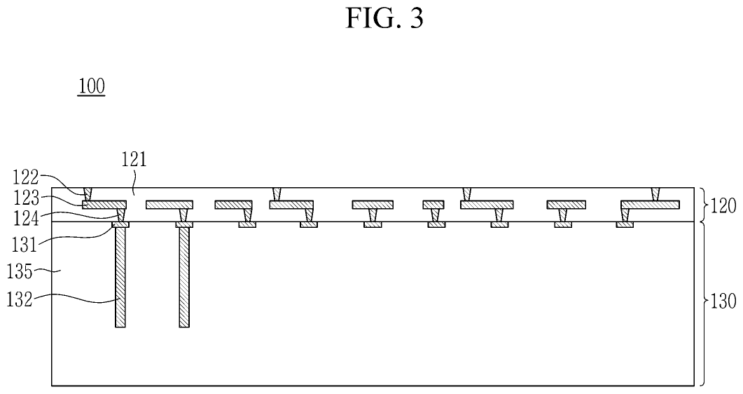

FIG. 3 illustrates a cross-sectional view of a step of forming the redistribution layer structure 120 on the first semiconductor die 130, in the manufacturing method of the semiconductor structure 100.

Referring to FIG. 3, the redistribution layer structure 120 is formed on a front side of the semiconductor die 130 (e.g., an active side that includes semiconductor circuit elements).

First, the lower connection pad 131 is formed to be connected to the through-silicon via (TSV) 132. In this embodiment, the lower connection pad 131 may be formed by depositing a silicon layer and then performing photo, development, etching, and electrolytic plating. For example, a silicon layer may be added on top of the die base 135 and TSVs 132, which layer may then be etched to form recesses, which are filled via electrolytic plating with metal material. In one embodiment, the lower connection pad 131 may include or be formed of at least one of copper, aluminum, silver, tin, gold, nickel, lead, titanium, and an alloy thereof.

Next, the dielectric layer 121 is formed on the lower connection pad 131 and the silicon layer or on the semiconductor die 130. Since the dielectric layer 121 is directly formed on the lower connection pad 131 and the silicon layer or on the semiconductor die 130, connection members such as micro bumps and solder bumps are not used. A front side of the semiconductor die 130 may contact an outer surface of the redistribution layer structure. In one embodiment, the dielectric layer 121 may include or be a photosensitive polymer layer. The photosensitive polymer is a material that may form fine patterns by applying a photolithography process. In one embodiment, the dielectric layer 121 may include or be a photoimageable dielectric (PID) used in a redistribution process. As an example, the PID may be a polyimide-based photosensitive polymer, a novolak-based photosensitive polymer, polybenzoxazole, a silicon-based polymer, an acrylate-based polymer, or an epoxy-based polymer. In another embodiment, the dielectric layer 121 is formed of a polymer such as a PBO, a polyimide, or the like. In some embodiments, the dielectric layer 121 is made of an inorganic dielectric material such as a silicon nitride, a silicon oxide, or the like. In one embodiment, the dielectric layer 121 may be formed by a CVD, ALD, or PECVD process.

After forming the dielectric layer 121, the dielectric layer 121 is selectively etched to form the via holes, and the via holes are filled with a conductive material to form the redistribution vias 124. A width of an uppermost portion of each of the second redistribution vias 124 is greater than a width of a lowermost portion thereof. In a subsequent process, since a final product is manufactured by overturning the first semiconductor die 130 on which the redistribution layer structure 120 is formed, in the final product, the width of the uppermost portion of each of the second redistribution vias 124 is smaller than that of the lowermost portion thereof.

Next, the dielectric layer 121 is additionally deposited on the second redistribution vias 124 and the dielectric layer 121, the additionally deposited dielectric layer 121 is selectively etched to form openings, and the openings are filled with a conductive material to form the redistribution lines 123.

Next, the dielectric layer 121 is additionally deposited on the first redistribution lines 123 and the dielectric layer 121, the additionally deposited dielectric layer 121 is selectively etched to form via holes, and the via holes are filled with a conductive material to form the redistribution vias 122. For the same reason as the second redistribution vias 124, in the final product, in one embodiment, a width of an uppermost portion of each of the first redistribution vias 122 is smaller than that of a lowermost portion thereof.

In one embodiment, the first redistribution vias 122, the first redistribution lines 123, and the second redistribution vias 124 may include or be formed of at least one of copper, aluminum, tungsten, nickel, gold, tin, titanium, an alloy thereof, and the like. In one embodiment, the first redistribution vias 122, the first redistribution lines 123, and the second redistribution vias 124 may be formed by performing a sputtering process. In another embodiment, the first redistribution vias 122, the first redistribution lines 123, and the second redistribution vias 124 may be formed by performing an electroplating process after forming a seed metal layer. The redistribution layer structure 120 may therefore include a plurality of redistribution lines and redistribution vias at different vertical levels, formed within a dielectric layer 121. The dielectric layer may be formed of a single material, deposited in layers to form a unitary final dielectric layer 121. Though one layer of redistribution lines and two layers of redistribution vias are shown, other amounts of these layers may be deposited to form the redistribution layer structure 120.

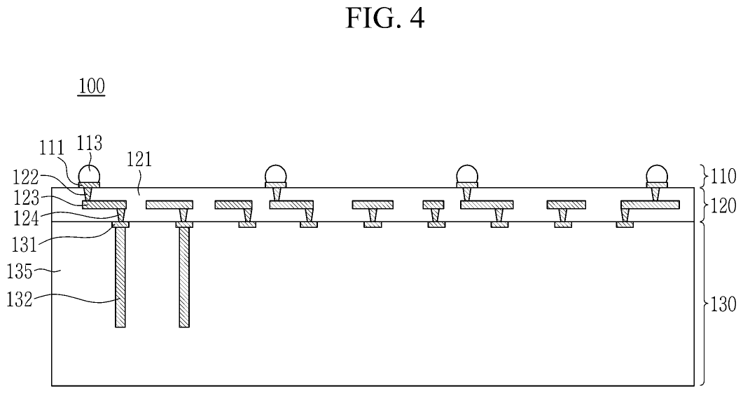

FIG. 4 illustrates a cross-sectional view of a step of forming the interconnection structure 110 on the redistribution layer structure 120, in the manufacturing method of the semiconductor structure 100.

Referring to FIG. 4, the interconnection structure 110 is formed on the redistribution layer structure 120. The conductive pads 111 are formed on the dielectric layer 121 of the redistribution layer structure 120, and the connection members 113 are formed on the conductive pads 111. In one embodiment, the conductive pad 111 may include or be formed of at least one of copper, nickel, zinc, gold, silver, platinum, palladium, chromium, titanium, and an alloy thereof. In one embodiment, the conductive pad 111 may be formed by performing a sputtering process, or by performing an electroplating process after forming a seed metal layer. In one embodiment, the connection member 113 may include or be formed of at least one of tin, silver, lead, nickel, copper, and an alloy thereof, and may be a solder ball or bump.

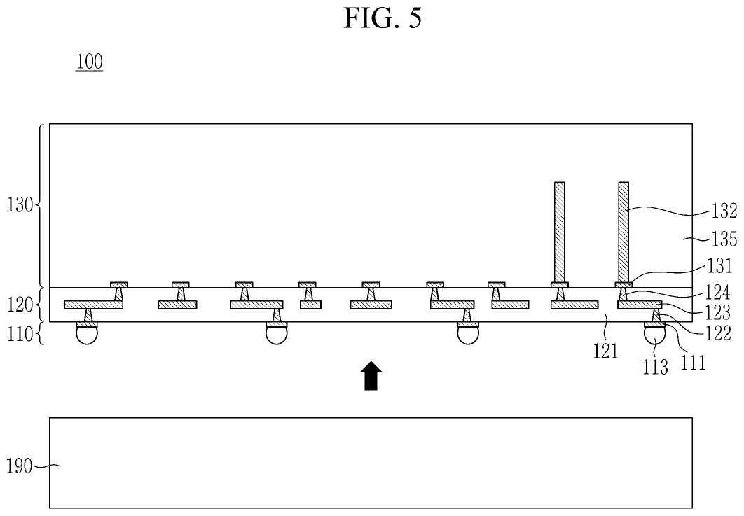

FIG. 5 illustrates a cross-sectional view of a step of bonding a carrier 190 under the interconnection structure 110, in the manufacturing method of the semiconductor structure 100.

Referring to FIG. 5, the semiconductor die 130 on which the interconnection structure 110 and the redistribution layer structure 120 are formed is reversed (e.g., flipped) and aligned, and by performing a wafer supporting system, the carrier 190 is bonded under the interconnection structure 110 and the redistribution layer structure 120. The carrier 190 may include or be formed of, for example, a silicon-based material such as glass or a silicon oxide, an organic material, or another material such as an aluminum oxide, a combination of these materials, and the like.

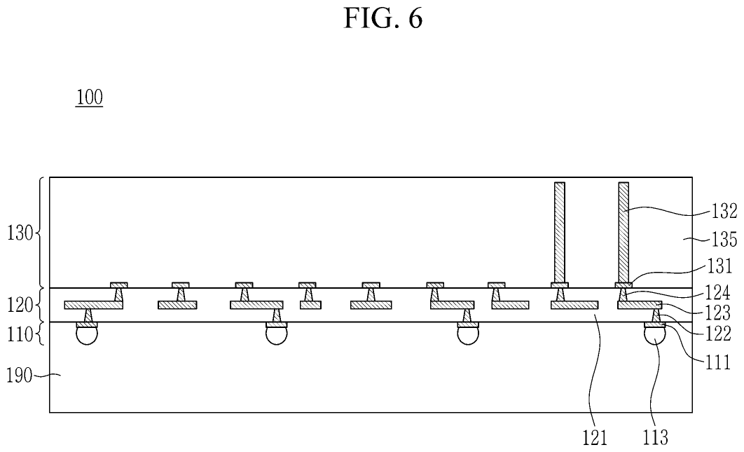

FIG. 6 illustrates a cross-sectional view of a step in which the semiconductor die 130 is completed by grinding the back side of the die base 135, in the manufacturing method of the semiconductor structure 100.

Referring to FIG. 6, the back side of the die base 135 is removed by grinding.

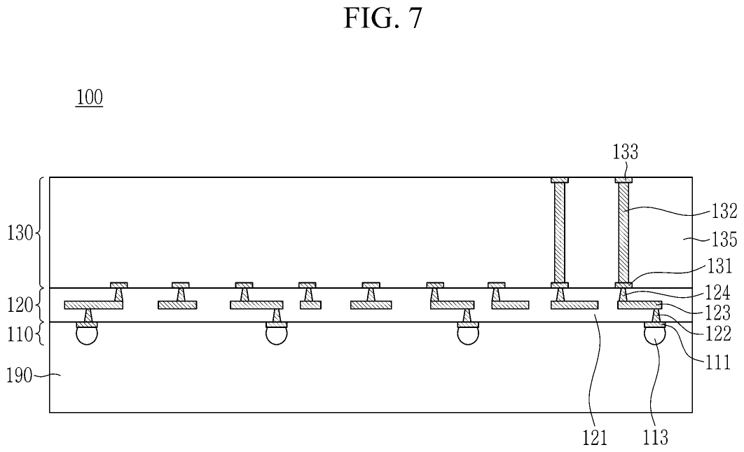

FIG. 7 illustrates a cross-sectional view of a step of forming the upper connection pads 133 of the semiconductor die 130, in the manufacturing method of the semiconductor structure 100.

Referring to FIG. 7, the upper connection pads 133 of the semiconductor die 130 are formed.

The upper connection pads 133 are formed to be connected to the through-silicon vias (TSVs) 132. In one embodiment, the upper connection pads 133 may be formed by performing photo, development, etching and electrolytic plating on the back side of the die base 135. In one embodiment, the upper connection pads 133 may include or be formed of at least one of copper, aluminum, silver, tin, gold, nickel, lead, titanium, and an alloy thereof.

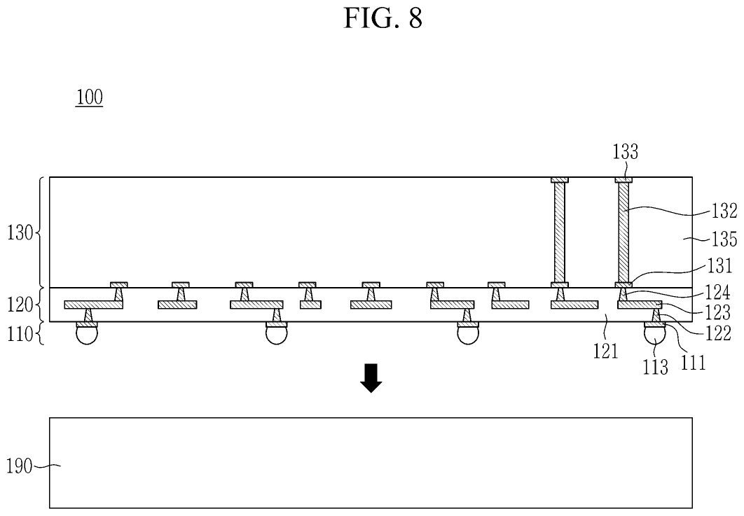

FIG. 8 illustrates a cross-sectional view of a step of removing the carrier 190 from the interconnection structure 110 and the redistribution layer structure 120, in the manufacturing method of the semiconductor structure 100. For example, the carrier 190 may be attached by an adhesive that can be easily removed.

Referring to FIG. 8, the carrier 190 is removed from the interconnect structure 110 and the redistribution layer structure 120.

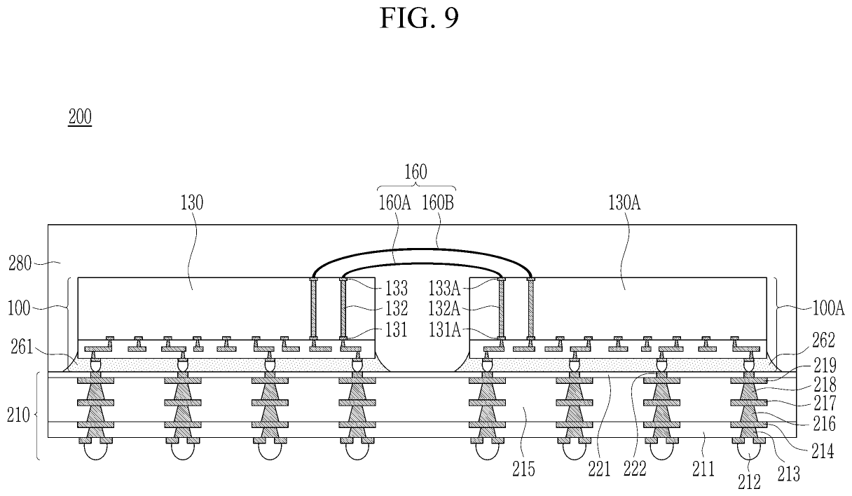

FIG. 9 illustrates a cross-sectional view of the semiconductor package 200 according to an embodiment.

Referring to FIG. 9, the semiconductor package 200 may include the substrate 210, the first semiconductor structure 100 including the first semiconductor die 130, a second semiconductor structure 100A including a second semiconductor die 130A, the bonding wires 160, a first insulating member 261, a second insulating member 262, and a molding material 280.

The substrate 210, also described as a package substrate, may include a first insulating layer 211, external connection members 212, connection pads 213, first bonding wire layers 214, a second insulating layer 215, and first vias 216, second bonding wire layers 217, second vias 218, third bonding wire layers 219, a third insulating layer 221, and connection members 222. In one embodiment, the substrate 210 may include or be an ajinomoto build-up film (ABF) substrate. In one embodiment, the substrate 210 may include or be a printed circuit board. In other embodiments, substrates including fewer or greater numbers of insulating layers, bonding wire layers, vias, external connection members, connection members, and connection pads are within the scope of the present disclosure.

The substrate 210 may include electrical routing for relaying signals from the first semiconductor die 130 and from the second semiconductor die 130A. For example, the substrate 210 may relay signals from a device external to the semiconductor package 200 to each of the first semiconductor die 130 and the second semiconductor die 130A. The substrate 210 may also relay signals between the first semiconductor die 130 and the second semiconductor die 130A. According to the present disclosure, since signals between the first semiconductor die 130 and the second semiconductor die 130A, each having a fine pitch I/O, may be exchanged through the substrate 210 without using a silicon bridge, the problem of a silicon bridge being moved or being inaccurately attached during the manufacturing process is avoided, and the problem of warpage of the semiconductor package due to the silicon bridge is avoided. As a result, the yield of semiconductor packages may be improved.

In addition, when a silicon bridge is used, the manufacturing process is more complicated because the silicon bridge is embedded in the substrate 210, while by not using the silicon bridge, the manufacturing process of the semiconductor package may be simplified.

In one embodiment, the connection pads 213, the first wire layer 214, the first vias 216, the second wire layer 217, the second vias 218, the third wire layer 219, and the connection members 222 may each include or be formed of at least one of copper, nickel, zinc, gold, silver, platinum, palladium, chromium, titanium, and an alloy thereof. In one embodiment, the first insulating layer 211 may include or be a solder resist. In one embodiment, the second insulating layer 215 may include or be formed of at least one of a thermosetting epoxy resin, and a resin containing a filler. In one embodiment, the third insulating layer 221 may include or be a solder resist. In one embodiment, the external connection member 212, also described as an external connection terminal, or a package connection terminal, may include or be formed of at least one of tin, silver, lead, nickel, copper, and an alloy thereof.

The first semiconductor structure 100 and the second semiconductor structure 100A may be disposed on the substrate 210. For the first semiconductor structure 100 and the second semiconductor structure 100A, the contents of the semiconductor structure 100 described and shown for FIG. 1 may be equally applied.

A plurality of bonding wires 160 are disposed on the first semiconductor structure 100 and on the second semiconductor structure 100A, and may serve to exchange signals from the first semiconductor die 130 and from the second semiconductor die 130A (e.g., between the first semiconductor die 130 and the second semiconductor die 130A). One end of each bonding wire of the plurality of bonding wires 160 may be electrically connected to a semiconductor chip (semiconductor integrated circuit) in the first semiconductor die 130 through the first through-silicon via 132 connected to the upper connection pad 133 of the first semiconductor die 130, and the other end of each bonding wire of the plurality of bonding wires 160 may be electrically connected to a semiconductor chip (semiconductor integrated circuit) in the second semiconductor die 130A through the second through-silicon via 132A connected to the upper connection pad 133A of the second semiconductor die 130A. Each of the bonding wires 160 may be bent to have a curved arc shape, the extends between two corresponding upper connection pads (e.g., 133 and 133A). Different bonding wires may have different lengths and different heights above a top surface of the semiconductor dies 130 and 130A. The top surfaces of the semiconductor dies 130 and 130A may be coplanar, or may be disposed at a different height.

The bonding wires 160 may include a first bonding wire 160A and a second bonding wire 160B. The bonding wires 160 may connect a back side of the first semiconductor die 130 and a back side of the second semiconductor die 130A. The first bonding wire 160A may electrically connect a first set of a first through-silicon via 132 and a second through-silicon via 132A disposed closest to each other. The second bonding wire 160B may electrically connect a second set of a first through-silicon via 132 and a second through-silicon via 132A disposed second closest to each other. The first bonding wire 160A may be disposed at a lower vertical level, and the second bonding wire 160B may be disposed above the first bonding wire 160B. For example, a plurality of bonding wires include a first set of bonding wires (e.g., first bonding wires 160A) that each reach a first height above a top surface of the substrate 210, and a second set of bonding wires (e.g., second bonding wires 160B) that each reach a second height above the top surface of the substrate, the second height being higher than the first height. The first set of bonding wires may include first bonding wires each having a first length (and spanning a first horizontal distance) and the second set of bonding wires may include second bonding wires each having a second length (and spanning a second horizontal distance) greater than the first length (or distance).

In another embodiment, the plurality of bonding wires 160 may include first to N-th sets of bonding wires (where N is a natural number greater than or equal to 2). In the embodiment of FIG. 10, the first bonding wires 160A and the second bonding wires 160B are shown, but more or fewer bonding wires may be included in the scope of the present disclosure. The first bonding wire 160A may electrically connect a first set of first through-silicon via 132 and second through-silicon via 132A disposed closest to each other (e.g., in first rows closest to each other). An n-th bonding wire (n is a natural number from 2 to N) may electrically connect an n-th set of first through-silicon via 132 and second through-silicon via 132A disposed n-th closest to each other (e.g., in each of n rows). Each corresponding first bonding wire 160A to N-th bonding wire may be sequentially disposed from a lower vertical level to a higher vertical level (e.g., so that an upper-most portion of the first bonding wire 160A is lower than an upper-most portion of a second bonding wire 160B, and an upper-most portion of the second bonding wire 160B is lower than an upper-most portion of an N-th bonding wire. Therefore, as can be seen from FIGS. 9 and 10, two semiconductor chip structures (e.g., 130 and 130A) may be placed horizontally adjacent to each other on a package substrate (e.g., 210). A first edge of the first semiconductor chip structure 130 may face a first edge of the second semiconductor chip structure 130A. A first row of upper connection pads 133 may be adjacent to the first edge of the first semiconductor chip structure 130, and a first row of upper connection pads 133A may be adjacent to the first edge of the second semiconductor chip structure 130A. Corresponding upper connection pads in these rows may be connected to each other by respective first bonding wires 160A. A second row of upper connection pads 133 may be adjacent to the first row of upper connection pads 133, so that the first row of the upper connection pads 133 is between the first edge of the first semiconductor chip structure 130 and the second row of the upper connection pads 133. A second row of upper connection pads 133A may be adjacent to the first row of upper connection pads 133A, so that the first row of the upper connection pads 133A is between the first edge of the second semiconductor chip structure 130A and the second row of the upper connection pads 133A. Corresponding upper connection pads in these rows may be connected to each other by respective second bonding wires 160B. The second bonding wires 160B (e.g., a set of second bonding wires) may reach a higher vertical height than the first bonding wires 160A (e.g., a set of first bonding wires) and have lengths longer than the first bonding wires 160A. Additional rows of upper connection pads and bonding wires may be included and connected up to N-th rows and bonding wires.

According to the present disclosure, the first bonding wires 160A and second bonding wires 160B may be connected to the first semiconductor chip structure 130 and second semiconductor chip structure 130A so that a first set of signals between the first semiconductor die 130 and the second semiconductor die 130A, each having a fine pitch I/O, may be exchanged through the substrate 210 without using a silicon bridge, and a second set of signals between the first semiconductor die 130 and the second semiconductor die 130A may be exchanged through the plurality of bonding wires 160.

The first set of signals may be signals from a semiconductor chip or portion of a semiconductor chip (semiconductor integrated circuits; for example, a wireless communication chip) including a relatively low-performance circuit, and thus may be a first type of signals (e.g., low-performance signals). The second set of signals may be signals from a semiconductor chip or portion of a semiconductor chip (semiconductor integrated circuits; for example, a central processing unit (CPU) or a graphics processing unit (GPU)) including a relatively high-performance circuit, and thus may be a second type of signals (e.g., high-performance signals). A speed of exchanging the second signals through the plurality of bonding wires 160 may be faster than a speed of exchanging the first signals through the substrate 210.

According to the present disclosure, the signals from the semiconductor chips (semiconductor integrated circuits) including the relatively low-performance circuits of the first semiconductor die 130 and the second semiconductor die 130A, each having the fine pitch I/O, may be exchanged through the substrate 210, and the signals from the semiconductor chips (semiconductor integrated circuits) including the relatively high-performance circuitry of the first semiconductor die 130 and the second semiconductor die 130A, each having the fine pitch I/O, may be exchanged directly between the first semiconductor die 130 and second semiconductor die 130A through the bonding wires 160, so that the signals may be transmitted more efficiently. The low and high performance may refer to a speed of a signal, or a frequency of a signal passing through a bonding wire path.

The first insulating member 261 may be disposed between the first semiconductor structure 100 and the substrate 210, and the second insulating member 262 may be disposed between the second semiconductor structure 100A and the substrate 210.

The first insulating member 261 may be disposed on the lower surface and a portion of the side surface of the first semiconductor structure 100, and may surround the interconnection members 113 of the first semiconductor structure 100. The second insulating member 262 may be disposed on the lower surface and a portion of the side surface of the second semiconductor structure 100A, and may surround the interconnection members 113A (corresponding to the interconnection members 113 of the first semiconductor structure 100) of the second semiconductor structure 100A. The first insulating member 261 and second insulating member 262 may be underfill materials, formed of an insulating material.

The molding material 280 may mold the first semiconductor structure 100, the second semiconductor structure 100A, the first insulating member 261, and the second insulating member 262 on the substrate 210.

FIG. 10 illustrates a top plan view of an upper surface of the semiconductor package 200 according to an embodiment.

FIG. 10 illustrates an upper surface of the semiconductor package 200 before being molded with the molding material 280.

Referring to FIG. 10, the bonding wires 160 may electrically connect the first upper connection pads 133 on the upper surface of the first semiconductor structure 100 and the second upper connection pads 133A on the upper surface of the second semiconductor structure 100A. According to FIG. 10, it is shown that the first upper connection pads 133 of 10×2 are included on the upper surface of the first semiconductor structure 100, the second upper connection pads 133A of 10×2 are included on the upper surface of the second semiconductor structure 100A, and the bonding wires 160 connect them, but the present disclosure is not limited thereto, and fewer or more first upper connection pads 133, second upper connection pads 133A, and bonding wires 160 may be included in the present disclosure.

For each row (e.g., in the X-direction as shown in FIG. 10), the bonding wires 160 may include first to N-th bonding wires (where N is a natural number greater than or equal to 2). In a plan view, the first to N-th bonding wires may be disposed to overlap. The first bonding wire 160A may electrically connect the first through-silicon via 132 connected to the first upper connection pad 133 and the second through-silicon via 132A connected to the second upper connection pad 133A, which are disposed closest to each other, and the N-th bonding wire may electrically connect the first through-silicon via 132 connected to the first upper connection pad 133 and the second through-silicon via 132A connected to the second upper connection pad 133A, which are disposed N-th closest to each other. For each row, middle portions, or upper-most portions of the first to N-th bonding wires may be sequentially disposed in a vertical direction from the bottom to top.

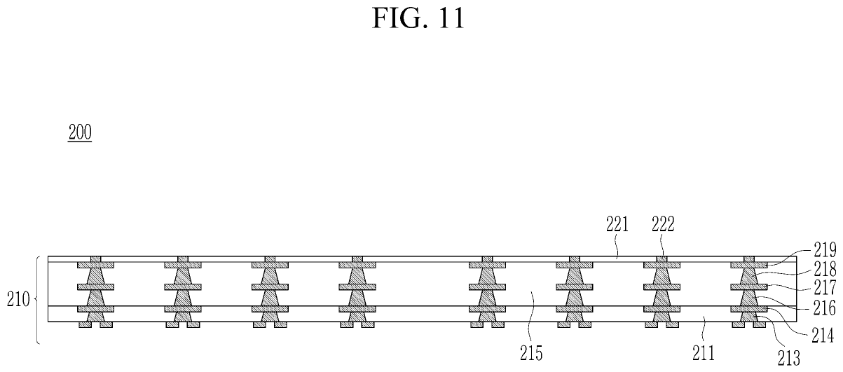

FIG. 11 to FIG. 16 illustrate cross-sectional views of a manufacturing method of the semiconductor package 200 of one embodiment.

FIG. 11 illustrates a cross-sectional view of a step of providing the substrate 210, in the manufacturing method of the semiconductor package 200.

Referring to FIG. 11, the substrate 210 is provided. Before the first semiconductor structure 100 and the second semiconductor structure 100A are mounted on the substrate 210, to clean the surface of the substrate 210, a pretreatment process using UV rays, plasma, or baking may be performed on the substrate 210.

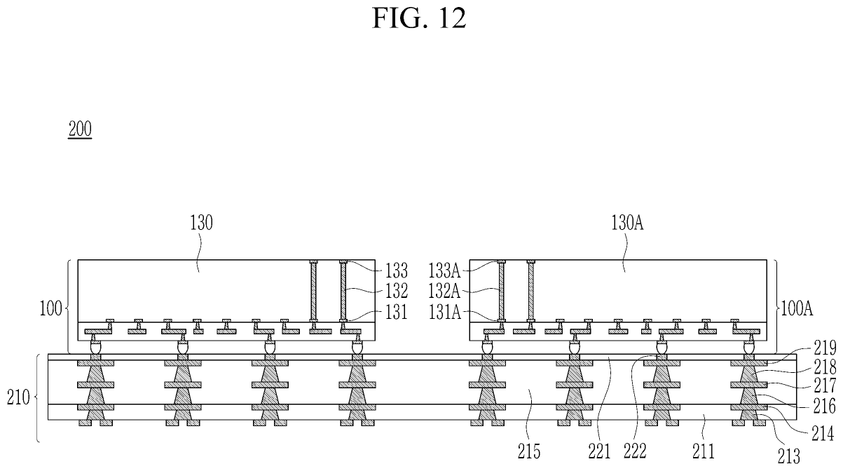

FIG. 12 illustrates a cross-sectional view of a step of mounting the first semiconductor structure 100 and the second semiconductor structure 100A on the substrate 210, in the manufacturing method of the semiconductor package 200.

Referring to FIG. 12, the first semiconductor structure 100 and the second semiconductor structure 100A are mounted on the substrate 210 by flip chip bonding.

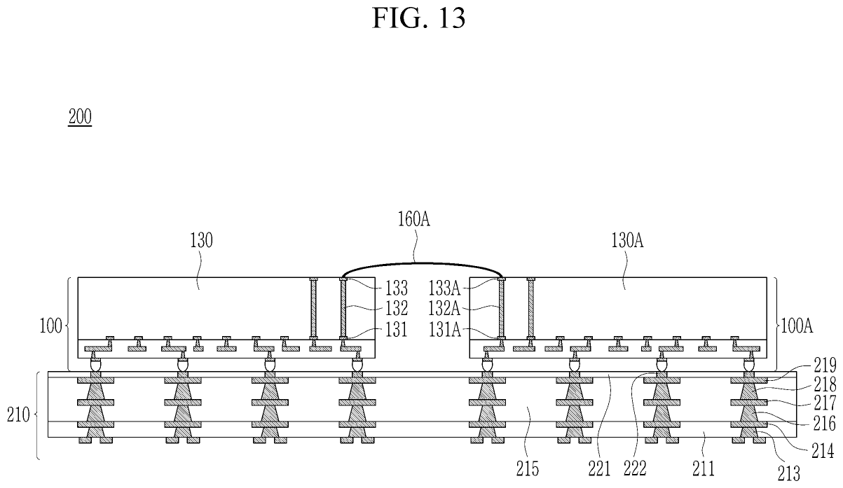

FIG. 13 illustrates a cross-sectional view of a step of connecting the first semiconductor structure 100 and the second semiconductor structure 100A with the first bonding wire 160A, in the manufacturing method of the semiconductor package 200.

Referring to FIG. 13, the first bonding wire 160A is bonded on the first interconnection pad 133 and the second upper connection pad 133A, which are closest to each other, for example by using a capillary (not shown) or a wedge (not shown). In this embodiment, before the bonding of the first bonding wire 160A on the first interconnection pad 133 and the second upper connection pad 133A, to improve adhesion between the first interconnection pad 133 and the first bonding wire 160A and between the second upper connection pad 133A and the first bonding wire 160A, a surface treatment process may be performed on the first interconnection pad 133 and the second upper connection pad 133A so as to reduce the surface roughness of the first interconnection pad 133 and the second upper connection pad 133A. In the embodiment, the first bonding wire 160A may include or be formed of at least one of gold, silver, copper, and an alloy thereof.

In one embodiment, the first bonding wire 160A may be bonded to the first interconnection pad 133 and the second upper connection pad 133A by performing a thermal compression bonding process, an ultrasonic process, or a thermal ultrasonic process.

The thermal compression bonding process is performed by applying heat to the tip of the capillary to make the one end of the bonding wire 160A into a ball shape, and compressing the first bonding wire 160A to the first interconnection pad 133 and the second upper connection pad 133A heated through the capillary. The ultrasonic process is performed by placing the first bonding wire 160A on the first interconnection pad 133 and the second upper connection pad 133A, applying pressure and ultrasonic waves to the first bonding wire 160A through a wedge (not shown), and compressing the first bonding wire 160A to the first interconnection pad 133 and the second upper connection pad 133A. The thermal ultrasonic process is performed by applying heat to the tip of the capillary to make one end of the first bonding wire 160A into a ball shape, and applying heat and pressure ultrasonic vibration to the capillary to compress the first bonding wire 160A to the heated first interconnection pad 133 and the second upper connection pad 133A. A result of any of these processes is that the bonding wires are connected to respective pads without the use of a solder material or soldering process, such that the bonding wires can be directly connected to and bonded to the respective pads.

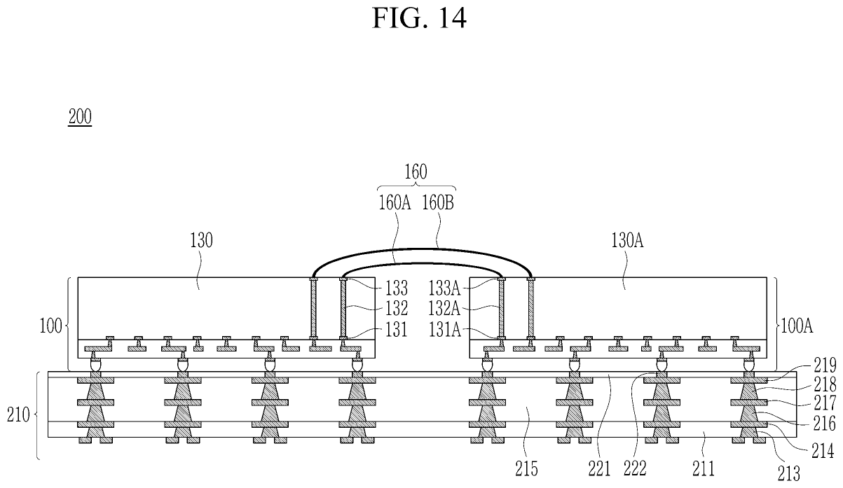

FIG. 14 illustrates a cross-sectional view of a step of connecting the first semiconductor structure 100 and the second semiconductor structure 100A with the second bonding wire 160B, in the manufacturing method of the semiconductor package 200.

Referring to FIG. 14, the second bonding wire 160B is bonded on the first interconnection member 133 and the second upper connection pad 133A, which are second closest, by using a capillary (not shown) or a wedge (not shown). The bonding of the first bonding wire 160A described with reference to FIG. 13 may be equally applicable to the bonding of the second bonding wire 160B.

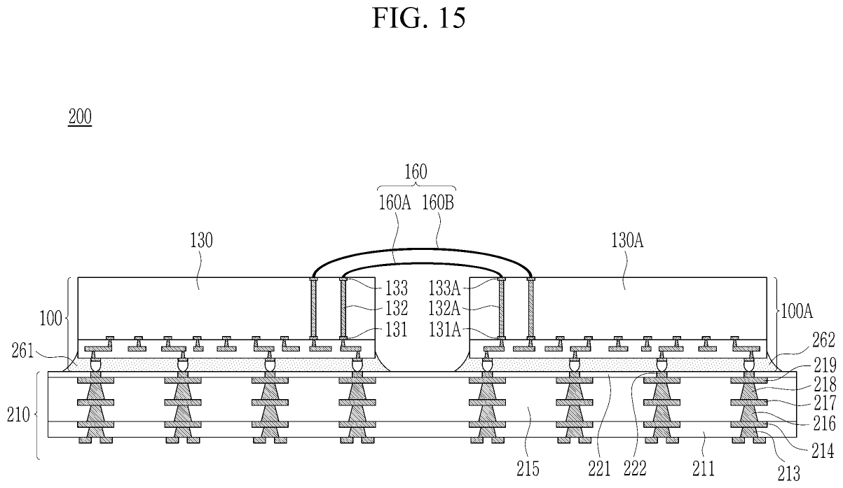

FIG. 15 illustrates a cross-sectional view of a step of forming the first insulating member 261 between the substrate 210 and the first semiconductor structure 100 and forming the second insulating member 262 between the substrate 210 and the second semiconductor structure 100A, in the manufacturing method of the semiconductor package 200.

Referring to FIG. 15, the first insulating member 261 is formed on the lower surface and a portion of the side surface of the first semiconductor structure 100, and the second insulating member 262 is formed on the lower surface and a portion of the side surface of the second semiconductor structure 100A. In one embodiment, each of the first insulating member 261 and the second insulating member 262 may include a non-conductive film (NCF). In this embodiment, each of the first insulating member 261 and the second insulating member 262 may include or be, for example, a molded under-fill (MUF).

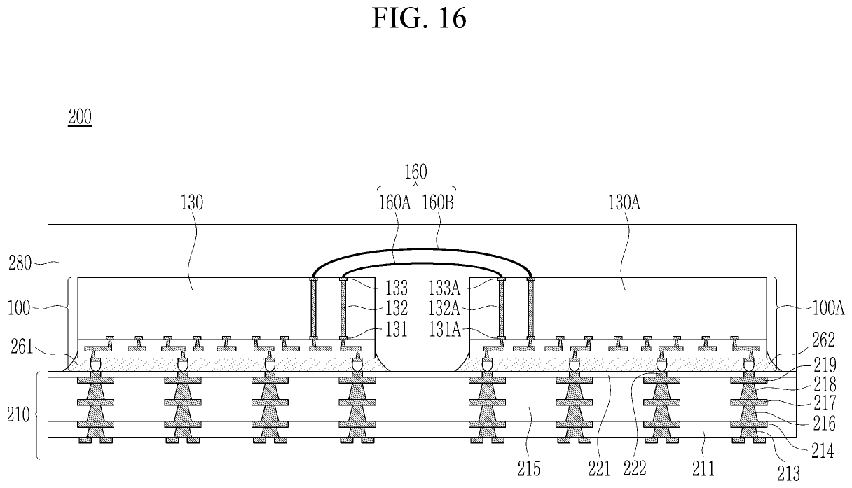

FIG. 16 illustrates a cross-sectional view of a step of molding the first semiconductor structure 100 and the second semiconductor structure 100A with the molding material 280 on the substrate 210, in the manufacturing method of the semiconductor package 200.

Referring to FIG. 16, the first semiconductor structure 100 and the second semiconductor structure 100A are molded with the molding material 280 on the substrate 210. In one embodiment, the process of molding with the molding material 280 may include a compression molding or transfer molding process. In this embodiment, the molding material 280 may include or be, for example, an epoxy molding compound (EMC).

After that, the external connection members 212 are formed on the lower surface of the substrate 210.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

What is claimed is:

1. A semiconductor package comprising:
a substrate;
a first semiconductor structure on the substrate, wherein the first semiconductor structure includes:
a first redistribution layer structure, and
a first semiconductor die that is disposed on the first redistribution layer structure and includes a plurality of first through-semiconductor vias;
a second semiconductor structure disposed side by side with the first semiconductor structure on the substrate, wherein the second semiconductor structure includes:
a second redistribution layer structure, and
a second semiconductor die that is disposed on the second redistribution layer structure and includes a plurality of second through-semiconductor vias;
a plurality of bonding wires electrically connecting the first semiconductor die and the second semiconductor die on the first semiconductor die and the second semiconductor die.

2. The semiconductor package of claim 1, wherein:
the first semiconductor die and the second semiconductor die are connected to exchange a first type of signal through the substrate and to exchange a second type of signal through the plurality of bonding wires.

3. The semiconductor package of claim 2, wherein:
the second type of signals are relatively high speed signals exchanged through the plurality of bonding wires at a relatively faster speed than the first type of signals, which are relatively low speed signals having a relatively lower speed than the relatively high speed signals, and are exchanged through the substrate at a relatively slower speed.

4. The semiconductor package of claim 1, further comprising:
a molding material molding the first semiconductor structure, the second semiconductor structure, and the plurality of bonding wires on the substrate.

5. The semiconductor package of claim 1, wherein:
the plurality of bonding wires include first to N-th sets of bonding wires (where N is a natural number of 2 or more), and
the first to N-th sets of bonding wires are sequentially disposed from lower to higher heights above the substrate.

6. The semiconductor package of claim 1, wherein:
the plurality of bonding wires connect a back side of the first semiconductor die and a back side of the second semiconductor die.

7. The semiconductor package of claim 1, wherein:
a front side of the first semiconductor die contacts an upper surface of the first redistribution layer structure, and
a front side of the second semiconductor die contacts an upper surface of the second redistribution layer structure.

8. The semiconductor package of claim 1, wherein:
at least one of the first semiconductor die and the second semiconductor die includes a system on chip (SOC).

9. The semiconductor package of claim 1, wherein:
the plurality of bonding wires include at least one of gold, silver, copper, and an alloy thereof.

10. The semiconductor package of claim 1, wherein:
the substrate is an Ajinomoto build-up film (ABF) substrate.

11. A semiconductor package comprising:
a substrate;
a first semiconductor structure on the substrate, wherein the first semiconductor structure includes:
a first redistribution layer structure,
a plurality of first connection terminals electrically connecting the first redistribution layer structure to the substrate,
a first insulating member surrounding the plurality of first connection terminals between the substrate and the first redistribution layer structure, and
a first semiconductor die that is disposed on the first redistribution layer structure and includes a plurality of first through-semiconductor vias;
a second semiconductor structure disposed side by side with the first semiconductor structure on the substrate, wherein the second semiconductor structure includes:
a second redistribution layer structure,
a plurality of second connection terminals electrically connecting the second redistribution layer structure to the substrate,
a second insulating member surrounding the plurality of second connection terminals between the substrate and the second redistribution layer structure, and
a second semiconductor die that is disposed on the second redistribution layer structure and includes a plurality of second through-semiconductor vias; and
a plurality of bonding wires electrically connecting the first semiconductor die and the second semiconductor die on the first semiconductor die and the second semiconductor die.

12. The semiconductor package of claim 11, wherein:
the first semiconductor die includes a plurality of first upper connection pads;
a lower surface of each of the plurality of first upper connection pads contacts a respective first through-semiconductor via of the plurality of first through-semiconductor vias, and an upper surface of each of the first upper connection pads is exposed from an upper surface of the first semiconductor die;
the second semiconductor die includes a plurality of second upper connection pads; and
a lower surface of each of the plurality of second upper connection pads contacts a respective second through-semiconductor via of the plurality of second through-semiconductor vias, and an upper surface of each of the second upper connection pads is exposed from an upper surface of the second semiconductor die.

13. The semiconductor package of claim 12, wherein:
a first end of each of the plurality of bonding wires is connected to the upper surface of a respective first upper connection pad, and a second end of each of the plurality of bonding wires is connected to the upper surface of a respective second upper connection pad.

14. The semiconductor package of claim 11, wherein:
the plurality of first connection terminals and the plurality of second connection terminals include micro bumps.

15. The semiconductor package of claim 11, wherein:
the first insulating member and the second insulating member include a molded underfill (MUF).

16. The semiconductor package of claim 11, wherein:
the first insulating member and the second insulating member include a non-conductive film (NCF).

17. The semiconductor package of claim 11, further comprising:
a molding material surrounding the plurality of bonding wires and through which the plurality of bonding wires pass.

18. The semiconductor package of claim 11, wherein:
adjacent first connection terminals among the plurality of first connection terminals and adjacent second connection terminals among the plurality of second connection terminals have first pitches;
adjacent first through-semiconductor vias among the plurality of first through-semiconductor vias and adjacent second through-semiconductor vias among the plurality of second through-semiconductor vias have second pitches; and
the first pitch is greater than the second pitch.

19. The semiconductor device of claim 11, wherein:
the plurality of bonding wires include a first set of bonding wires that reaches a first height above a top surface of the substrate, and a second set of bonding wires that reaches a second height above the top surface of the substrate, the second height being higher than the first height.

20. The semiconductor device of claim 19, wherein:
the first set of bonding wires include first bonding wires each having a first length and the second set of bonding wires include second bonding wires each having a second length greater than the first length.
